(19) United States
(12) Patent Application Publication
(10) Pub. No.: US 2012/0327573 A1
(43) Pub. Date: Dec. 27, 2012

(54) ELECTRICAL DEVICE HAVING A BATTERY PACK

(76) Inventor: Rainer GLAUNING, Leinfelden-Echterdingen (DE)

(21) Appl. No.: 13/523,513

(22) Filed: Jun. 14, 2012

(30) Foreign Application Priority Data
Jun. 21, 2011 (DE) 10 2011 077 850.0

(51) Int. Cl. H05K 7/02; H01M 10/50

(52) U.S. Cl. 361/679.01; 429/71

(57) ABSTRACT

In an electrical device having a device housing which has an interface for electrical and mechanical connection to an associated battery pack, at least one connecting element is provided at the interface for electrically conductive connection to a contact element associated with the battery pack. At least one of the electrical device and the battery pack is designed to generate, during operation, an air stream which is supplied to the connecting element and the contact element to enable cleaning of the connecting element and the contact element by the air stream.

### BACKGROUND OF THE INVENTION

1. Field of the Invention

The present invention relates to an electrical device having a device housing which has an interface for electrical and mechanical connection to an associated battery pack, at least one connecting element for the electrically conductive connection to the contact element associated with the battery pack being provided at the interface.

2. Description of the Related Art

Electrical devices of this type are known from the related art which, for example, are designed as portable, battery-powered power tools which may be used in various ways, e.g., as construction and garden tools. Battery-powered hedge trimmers and lawn mowers, in particular, are known from gardening, which have an interface for the mechanical and electrical connection to an associated battery pack. This interface may be sealed using an associated sealing lip to prevent moisture and wetness from entering the interface.

The related art has the disadvantage that battery-powered power tools of this type are provided for outdoor gardening activities but they are only designed for limited use in moist or wet surroundings, since a corresponding sealing lip is only effective if the battery pack is plugged in. If the battery pack is exchanged in moist or wet surrounding conditions, e.g., during outdoor use in rainy conditions, the sealing lip does not provide any protection and water may enter the interface and lead to contact corrosion and/or malfunction.

### BRIEF SUMMARY OF THE INVENTION

One object of the present invention is to provide a new electrical device having a cordless power supply, in particular with the aid of a battery pack using which at least adequate protection of the contact elements associated with the battery pack is made possible even for wet and moist surrounding conditions.

This object is achieved by an electrical device having a device housing which has an interface for the electrical and mechanical connection to an associated battery pack. At least one connecting element for the electrically conductive connection to a contact element associated with the battery pack is provided at the interface. The electrical device and/or the battery pack is/are designed to generate, during operation, an air stream which is suppliable at least to the connecting element and the contact element to enable cleaning of the connecting element and the contact element by the air stream.

The present invention thus allows for the provision of an electrical device in which the connecting and contact elements, which are electrically conductively interconnected at the interface, are cleaned reliably by an air stream supplied during the operation of the electrical device-and are efficiently dried, if necessary.

A drive motor is preferably situated in the device housing, an operation of the drive motor causing the air stream to be generated.

The generation of the air stream may thus be implemented in a simple and cost-effective manner.

According to one specific embodiment, a fan is provided for the generation of the air stream.

The invention thus allows a relatively strong and targeted air stream to be generated for the cleaning and/or drying of the connecting and contact elements.

The fan is preferably situated in the device housing.

Thus, an electrical device having a compact and robust structure may be provided.

According to one specific embodiment, the electrical device is provided at least for operation in moist working environments, a moisture sensor for detecting moist surrounding conditions being provided on the device housing. This moisture sensor is designed in such a way that the air stream is generated upon detection of moist surrounding conditions.

The present invention thus allows, the air stream for the cleaning and/or drying of the connecting and contact elements to be generated by the electrical device as necessary in a simple manner.

According to one specific embodiment, the fan is situated in a battery pack housing of the battery pack.

A structural change of the electrical device per se may thus advantageously be dispensed with.

The electrical device is preferably provided at least for operation in moist working environments, a moisture sensor for detecting moist surrounding conditions being provided on the battery pack housing. This moisture sensor is designed in such a way that the air stream is generated upon detection of moist surrounding conditions.

The present invention thus allows the air stream for the cleaning and/or drying of the connecting and contact elements to be generated by the electrical device in an uncomplicated and efficient manner and as necessary.

According to one specific embodiment, the electrical device is designed as a power tool, in particular a garden tool, or as a charging device.

The present invention thus makes it possible to use the air stream for cleaning and/or drying the connecting and contact elements of an electrical device as well as an associated battery pack for a plurality of various devices in a simple manner.

The object mentioned at the outset is also achieved with the aid of a battery pack having at least one associated contact element for electrical contacting of an associated electrical device. A fan is provided for generating an air stream which is suppliable to the contact element to enable cleaning of the at least one contact element by the air stream.

The present invention thus allows for the provision of a battery pack whose contact elements are cleaned safely and reliably by an air stream, supplied during the operation of the battery pack, and are efficiently dried, if necessary.

The object mentioned at the outset is also achieved with the aid of an electrical device having a device housing into which at least one battery cell is integrated and on which at least one connecting element for the electrically conductive connection to a contact element of an associated charging device is provided. The electrical device is designed to generate, during operation, an air stream which is suppliable at least to the connecting element to enable cleaning of the connecting element by the air stream.

The present invention thus allows for the provision of an electrical device having integrated battery cells whose connecting elements are cleaned safely and reliably by an air stream supplied during the operation of the electrical device and are efficiently dried, if necessary.

### BRIEF DESCRIPTION OF THE DRAWINGS

FIG. 1 shows a schematic sectional view of an electrical device according to a first specific embodiment having an exchangeable battery pack according to a first specific embodiment.

FIG. 2 shows a schematic sectional view of an electrical device according to a second specific embodiment having the exchangeable battery pack of FIG. 1.

FIG. 3 shows a schematic sectional view of a battery pack according to a second specific embodiment.

FIG. 4 shows a schematic sectional view of a battery pack according to a third specific embodiment.

FIG. 5 shows a schematic sectional view of an electrical device according to a third specific embodiment having an exchangeable battery pack according to a fourth specific embodiment.

FIG. 6 shows a schematic sectional view of a system having an electrical device according to a fourth specific embodiment having fixedly integrated battery cells.

FIG. 7 shows a schematic sectional view of a system having an electrical device according to a fifth specific embodiment having fixedly integrated battery cells.

### DETAILED DESCRIPTION OF THE INVENTION

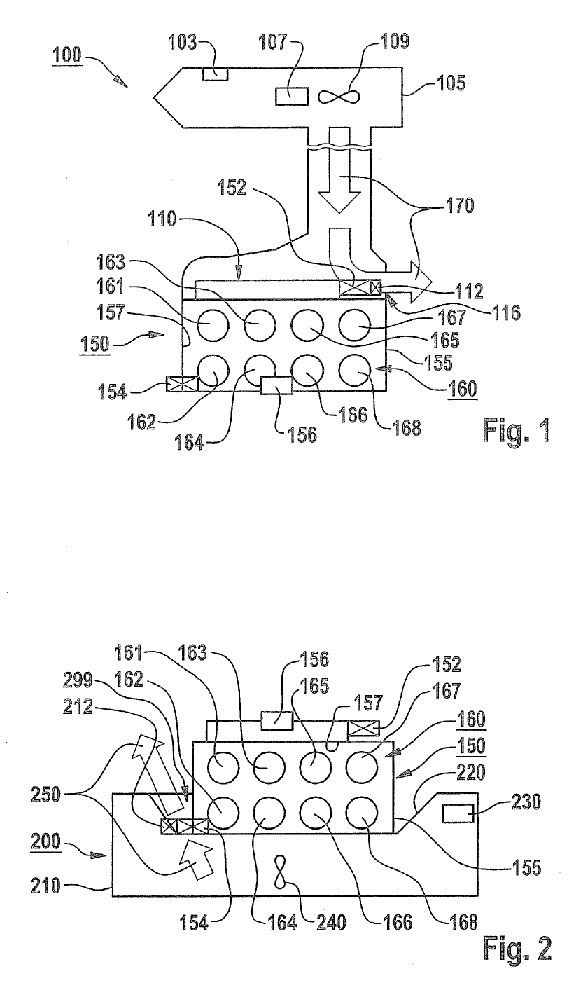

FIG. 1 shows an electrical device 100 having a device housing 105 on which an interface 110 for mechanical and electrical connection to a battery pack 150 is illustratively provided in order to enable a cordless power supply of electrical device 100. In or on device housing 105, a drive motor 107 and an optional fan 109, as well as a first optional moisture sensor 103 for detecting moist surrounding conditions are situated as an example.

In FIG. 1, electrical device 100 is designed as a cordless combi drill as an example. It is, however, pointed out that the present invention is not limited to cordless combi drills, but may rather be used for various battery-operated power tools, e.g., for a percussion drill or an angle grinder, and in particular for a battery-operated power tool which is provided for operation in potentially moist working environments, e.g., garden tools such as a hedge trimmer, a lawn mower, etc.

According to one specific embodiment, for example, guiding grooves and latching elements are provided at or in interface 110 for guiding and latching of battery pack housing 155 associated with battery pack 150, battery pack housing 155 having appropriate guiding rails and counter-latching elements which cooperate with the guiding grooves and latching elements in order to establish a mechanical connection between cordless combi drill 100 and battery pack 150. For this purpose, the mechanical connection is preferably established in such a way that an air outlet opening 116 is formed in the area between cordless combi drill 100 and battery pack 150. For the sake of simplification of the drawing, an illustration of the guiding grooves and latching elements as well as the guiding rails and the counter-latching elements was dispensed with since these are sufficiently known from the related art to those skilled in the art.

In the illustration, battery pack 150 is designed as a replaceable battery pack and has one or multiple battery cells 160. As an example, battery pack 150 has eight battery cells 161, 162, 163, 164, 165, 166, 167, 168 which are interconnected in series or in parallel depending on the battery type. These battery cells are illustratively situated in an inner chamber 157 formed by battery pack housing 155. To electrically connect battery pack 150 and cordless combi drill 100, at least one first contact element 152 is situated on battery pack housing 155, first contact element 152 being electrically conductively connected to one or multiple battery cells 160 on the one hand and, on the other hand, being electrically conductively connectable to a connecting element 112, which is associated with cordless combi drill 100 and provided at interface 110, as described below. The figure shows air outlet opening 116 in the area of first contact element 152 and connecting element 112. Moreover, a second optional moisture sensor 156 for detecting moist surrounding conditions is provided as an example on battery pack housing 155, as well as at least one second contact element 154 which is also electrically conductively connected to one or multiple battery cells 160 and is, for example, electrically conductively connectable to an associated connecting element of a charging device (212 or 200 in FIG. 2), as described below for FIG. 2.

According to one specific embodiment, connecting element 112, which is associated with cordless combi drill 100 and provided at interface 110, is electrically conductively connected to drive motor 107 and optional fan 109 in a direct or at least indirect manner. It is, however, pointed out that the structure and functionality of cordless combi drill 100, interface 110, and battery pack 150 are sufficiently known from the related art and are thus not further described here.

During operation of cordless combi drill 100, battery pack 150 is fastened, e.g., latched, to device housing 105 so that connecting element 112 is electrically conductively connected to contact element 152, an air stream 170 being able to be generated by operating drive motor 107 and/or by optional fan 109. This air stream is supplied to at least connecting element 112 and contact element 152 in the direction of air outlet opening 116 to enable cleaning of connecting element 112 and contact element 152 by air stream 170. Here, air stream 170 may be generated continuously during operation of cordless combi drill 100 or only periodically upon detection of moist surrounding conditions by first optional moisture sensor 103 and/or second optional moisture sensor 156, first and/or second moisture sensor 103, 156 being able to prompt the generation of air stream 170 at least indirectly.

For the case that connecting and contact elements 112 and 152 become moist or wet, during exchange of battery pack 150 in rainy conditions, for example, these may be dried and cleaned by air stream 170. In this case, moisture or wetness blown away from connecting and contact elements 112 and 152 by air stream 170, and the dirt particles blown away from connecting and contact elements 112 and 152, may be blown out of device housing 105 through air outlet opening 116.

FIG. 2 shows an electrical device 200 having a device housing 210 on which an interface 220 is illustratively provided for mechanical and electrical connection to a battery pack 150 of FIG. 1 which has at least one connecting element 212. In or on device housing 210, a fan 240 and an optional moisture sensor 230 for detecting moist surrounding conditions are situated as an example. As an example, electrical device 200 is designed as a charging device for charging battery pack 150, the charging device being mains-operated, for example.

In or at interface 220 illustratively designed as an insertion slot, for example, guiding grooves and latching elements for guiding and latching of battery pack housing 155 may be provided which cooperate with the guiding rails and counter-latching elements of battery pack housing 155 to establish a mechanical connection between charging device 200 and battery pack 150. For this purpose, the mechanical connection is preferably established in such a way that an air outlet opening 299 is formed in the area between charging device 200 and battery pack 150. For the sake of simplification of the drawing, a representation of the guiding grooves and latching elements as well as the guiding rails and the counter-latching elements was dispensed with since these are sufficiently known from the related art to those skilled in the art. Contact element 154 of battery pack 150, which is electrically conductively connectable to connecting element 212 of charging device 200, is used to establish an electrical connection between battery pack 150 and charging device 200. It is, however, pointed out that the structure and functionality of charging device 200 and interface 220 are sufficiently known from the related art and are thus not further described here.

During operation of charging device 200, battery pack 150 is held, e.g., latched, to device housing 210 so that connecting element 212 is electrically conductively connected to contact element 154, an air stream 250 being able to be generated by operating fan 240 when charging battery pack 150, for example. This air stream is supplied at least to connecting element 212 and contact element 154 in the direction of air outlet opening 299 to enable cleaning of connecting element 212 and contact element 154 by air stream 250, in a similar manner as described in FIG. 1. Here, air stream 250 may be generated continuously during operation of charging device 200 or only periodically upon detection of moist surrounding conditions by optional moisture sensor 156 of battery pack 150 and/or optional moisture sensor 230 of charging device 200, at least one of moisture sensors 156, 230 being able to prompt the generation of air stream 250 at least indirectly.

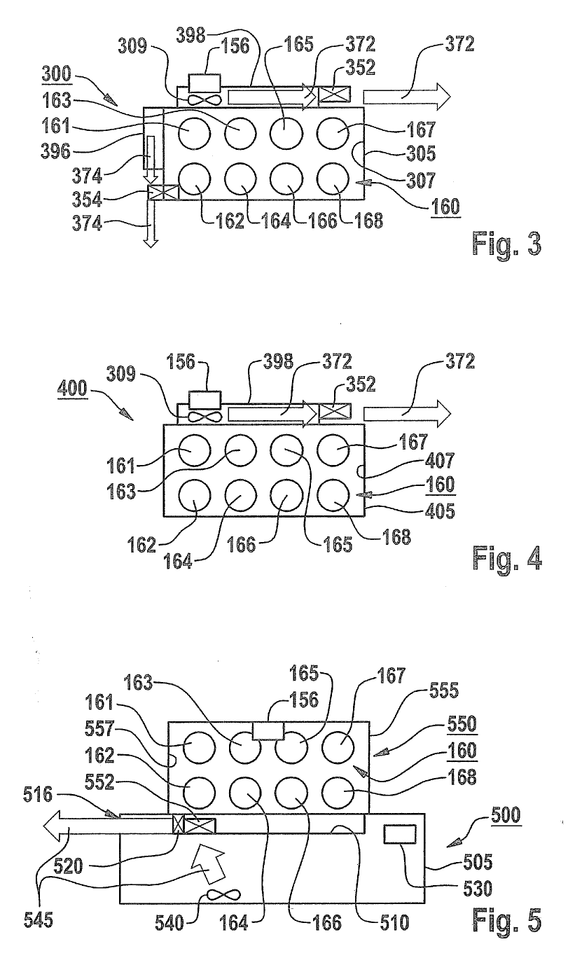

FIG. 3 shows a battery pack 300 designed as an example as a replaceable battery pack having a battery pack housing 305. Battery pack 300 illustratively has battery cells 160 of FIGS. 1 and 2, which are situated in an inner chamber 307 formed by a battery pack housing 305, and an optional moisture sensor 156 of FIGS. 1 and 2, which is situated on battery pack housing 305.

As an example, battery pack 300 has at least one first contact element 352 situated on battery pack housing 305, and one second contact element 354 situated on battery pack housing 305, each of which being electrically conductively connected to one or multiple of battery cells 160. First contact element 352 is, for example, used for the electrically conductive connection to connecting element 112 of cordless combi drill 100 of FIG. 1, and second contact element 354 is, for example, used for the electrically conductive connection to connecting element 212 of charging device 200 of FIG. 2.

According to one specific embodiment, battery pack 300 illustratively has a fan 309 situated in battery pack housing 305. As an example, this fan is connected to first contact element 352 via a first air guide channel 398 and to second contact element 354 via a second air guide channel 396.

During operation and/or in the event of nonuse of battery pack 300 during which battery pack 300 does not necessarily need to be connected to an associated electrical device (for example, cordless combi drill 100 of FIG. 1 or charging device 200 of

FIG. 2), air streams 372, 374 may be generated by an operation of fan 309. These air streams are supplied to contact elements 352 and 354 via air guide channels 398, 396 in order to enable cleaning or drying of these contact elements 352, 354 by air streams 372, 374. Here, air streams 372, 374 may be generated continuously or only periodically upon detection of moist surrounding conditions by optional moisture sensor 156 of battery pack 300, moisture sensor 156 being able to prompt the generation of air streams 372, 374 at least indirectly.

FIG. 4 shows a battery pack 400 having a battery pack housing 405 which is designed as an example as a replaceable battery pack. Battery pack 400 illustratively has battery cells 160 of FIGS. 1 and 2, which are situated in an inner chamber 407 formed by battery pack housing 405, and optional moisture sensor 156 of FIGS. 1 and 2, which is situated on battery pack housing 405. Moreover, battery pack 400 illustratively has fan 309 of FIG. 3, which is situated in battery pack housing 405, for generating air stream 372 which is connected to contact element 352 via air guide channel 398.

According to one specific embodiment, battery pack 400 essentially corresponds to battery back 300 of FIG. 3 but has in contrast thereto neither second contact element 354 of FIG. 3 nor air guide channel 396 of FIG. 3 associated with it. Since, however, the structure and functionality of these battery packs 300, 400 coincide otherwise, a detailed description of battery pack 400 is dispensed with for the sake of a concise description.

FIG. 5 shows an electrical device 500 having a device housing 505 on which an air outlet opening 516 and an interface 510 for mechanical and electrical connection to a battery pack 550 are illustratively provided, interface 510 having at least one connecting element 520. In or on device housing 505, a fan 540 and an optional moisture sensor 530 for detecting moist surrounding conditions are situated as an example. As an example, electrical device 500 is designed as a charging device for charging battery pack 550, the charging device being mains-operated, for example.

Battery pack 550 illustratively has an associated battery pack housing 555 which forms an inner chamber 557 in which battery cells 160 of FIGS. 1 and 2 are situated as an example. In addition, optional moisture sensor 156 of FIG. 1 is situated on battery pack housing 555. Furthermore, at least one contact element 552 which is electrically conductively connected to one or multiple of battery cells 160 is provided on battery pack housing 555. This contact element is used for the electrically conductive connection to connecting element 112 of cordless combi drill 100 of FIG. 1 and also for the electrically conductive connection to connecting element 520 of charging device 500.

In or at interface 510 illustratively designed as an insertion slot, for example, guiding grooves and latching elements for guiding and latching of battery pack housing 555 may be provided which cooperate with the corresponding guiding rails and counter-latching elements of battery pack housing 555 to establish a mechanical connection between charging device 500 and battery pack 550. For the sake of simplification of the drawing, a representation of the guiding grooves and latching elements as well as the guiding rails and the counter-latching elements was dispensed with since these are sufficiently known from the related art to those skilled in the art.

During operation of charging device 500, battery pack 550 is preferably held on device housing 505, for example inserted into insertion slot 510, so that connecting element 520 is electrically conductively connected to contact element 552, an air stream 545 being able to be generated by operating fan 540 when charging battery pack 550. This air stream is supplied to at least connecting element 520 and contact element 552 in the direction of air outlet opening 516 to enable cleaning of connecting element 520 and contact element 552 by air stream 545, in a similar manner as described in FIG. 2. Here, air stream 545 may be generated continuously during operation of charging device 500 or only periodically upon detection of moist surrounding conditions by optional moisture sensor 156 of battery pack 550 and/or optional moisture sensor 530 of charging device 500, at least one of moisture sensors 156, 530 being able to prompt the generation of air stream 545 at least indirectly.

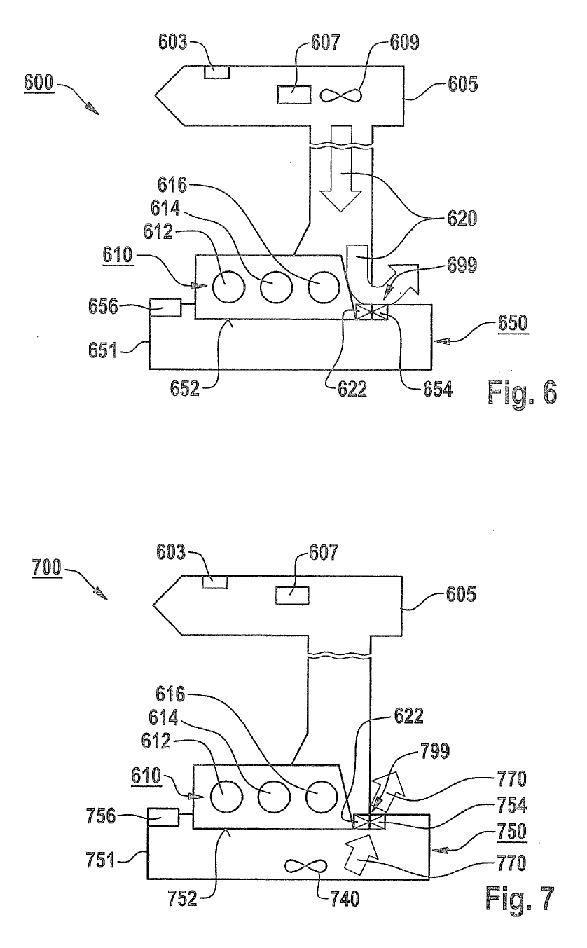

FIG. 6 shows an electrical device 600 which is illustratively situated in an associated charging device 650 and has a device housing 605 which has an air outlet opening 699 and into which one or multiple battery cells 610 are integrated in order to enable a mains-independent power supply of electrical device 600. As an example, three battery cells 612, 614, 616 are fixedly integrated into device housing 605 and are interconnected in parallel or in series depending on the device type, at least one of battery cells 610 being connected to an associated connecting element 622. In or on device housing 605, a drive motor 607 and an optional fan 609, as well as a first optional moisture sensor 603 for detecting moist surrounding conditions, are situated as an example. According to one specific embodiment, drive motor 607 and optional fan 609 are electrically conductively connected to battery cells 610 directly or at least indirectly.

In FIG. 6, electrical device 600 is designed as a cordless combi drill as an example. It is, however, pointed out that the present invention is not limited to cordless combi drills, but may rather be used for various battery-operated power tools, e.g., for a percussion drill or an angle grinder, and in particular for a battery-operated power tool which is provided for operation in potentially moist working environments, e.g., garden tools such as a hedge trimmer, a lawn mower, etc. It is also pointed out that the structure and functionality of cordless combi drill 600 and battery cells 610 are sufficiently known from the related art and are thus not further described here.

According to one specific embodiment, charging device 650 has a housing 651 on which an interface 652, which is designed as an insertion slot, is designed for accommodating cordless combi drill 600, at least one contact element 654 being provided at the interface. In addition, a second optional moisture sensor 656 is illustratively situated on housing 651.

During operation of cordless combi drill 600 and/or charging device 650, cordless combi drill 600 is held on housing 651, for example inserted into insertion slot 652, so that connecting element 622 is electrically conductively connected to contact element 654, an air stream 620 being able to be generated by operating drive motor 607 and/or by optional fan 609. This air stream 620 may also be generated if cordless combi drill 600 and charging device 650 are separated from one another.

Air stream 620 is supplied to at least connecting element 622 and contact element 654 in the direction of air outlet opening 699 to enable cleaning of connecting element 622 and contact element 654 by air stream 620, as described above. Here, air stream 620 may be generated continuously or only periodically upon detection of moist surrounding conditions by first optional moisture sensor 603 and/or second optional moisture sensor 656, first and/or second moisture sensors 603, 656 being able to prompt the generation of air stream 620 at least indirectly.

FIG. 7 shows an electrical device 700 which is illustratively situated in an associated charging device 750. Electrical device 700 essentially corresponds to electrical device 600 of FIG. 6 and is thus also referred to as “cordless combi drill” for the sake of simplicity; it, however, has in contrast thereto neither fan 609 of FIG. 6 nor air outlet opening 699 of FIG. 6.

Charging device 750 illustratively has a housing 751 on which an interface 752, which is designed as an insertion slot, is designed for accommodating cordless combi drill 700, at least one contact element 754 being provided at the interface. In addition, an optional moisture sensor 756 is illustratively situated on housing 751.

According to one specific embodiment, a fan 740 is situated in and an air outlet opening 799 is provided on housing 751. Fan 740 is used for generating an air stream 770 in the direction of air outlet opening 799 which is provided for cleaning and/or drying of connecting element 622 and contact element 754, in a similar manner as described in FIGS. 2 and 5, for example when charging battery cells 610, i.e., when cordless combi drill 700 is inserted in insertion slot 752.

It is explicitly pointed out that according to one specific embodiment, air streams generated in each case (170 in FIG. 1, 250 in FIG. 2, 372, 374 in FIG. 3, 372 in FIG. 4, 545 in FIG. 5, 620 in FIG. 6, and 770 in FIG. 7) are only used for cleaning and drying or blowing out of particular contact and connecting elements (152, 112 in FIG. 1, 154, 212 in FIG. 2, 352, 354 in FIG. 3, 352 in FIG. 4, 552, 520 in FIG. 5, 654, 622 in FIG. 6, and 754, 622 in FIG. 7), but not for cooling of associated battery cells (160 in FIGS. 1 through 5, 610 in FIGS. 6 and 7), for example.

What is claimed is:

1. An electrical system, comprising:
an electrical device having a device housing, wherein the device housing has an interface for electrical and mechanical connection to an associated battery pack; and
at least one connecting element provided at the interface for the electrical connection to a contact element associated with the battery pack;
wherein at least one of the electrical device and the battery pack is configured to generate, during operation, an air stream which is supplied at least to the connecting element and the contact element to clean the connecting element and the contact element by the air stream.

2. The electrical system as recited in claim 1, further comprising:
a drive motor situated in the device housing, wherein operation of the drive motor causes generation of the air stream.

3. The electrical system as recited in claim 2, further comprising:
a fan coupled to the drive motor, wherein operation of the fan by the drive motor generates the air stream.

4. The electrical system as recited in claim 3, wherein the fan is situated in the device housing.

5. The electrical system as recited in claim 3, further comprising:
a moisture sensor provided on the device housing for detecting moist surrounding conditions;
wherein the electrical system is configured for operation in moist working environments, and wherein the moisture sensor triggers, upon detection of moist surrounding conditions, the generation of the air stream.

6. The electrical system as recited in claim 3, wherein the fan is situated in a battery pack housing of the battery pack.

7. The electrical system as recited in claim 6, further comprising:
a moisture sensor provided on the battery pack housing for detecting moist surrounding conditions;
wherein the electrical system is configured for operation in moist working environments, and wherein the moisture sensor triggers, upon detection of moist surrounding conditions, the generation of the air stream.

8. The electrical system as recited in claim 5, wherein the electrical device is one of a power garden tool or a charging device.

9. A battery pack, comprising:
at least one contact element for electrically contacting an associated electrical device; and
a fan generating an air stream which is supplied to the contact element to clean the at least one contact element by the air stream.

10. An electrical device, comprising:
a device housing;
at least one battery cell integrated into the device; and
at least one connecting element provided on the device housing for electrical connection to a contact element of an associated charging device;
wherein the electrical device is configured to generate, during operation, an air stream which is supplied at least to the connecting element to clean the connecting element by the air stream.
